(19) United States
(12) Patent Application Publication
(10) Pub. No.: US 2005/0121739 A1
(43) Pub. Date: Jun. 9, 2005

(54) Method of manufacturing electro-optical device and annealing device for transparent substrate

(75) Inventor: Keiji Fukuhara, Eniwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/981,635

(22) Filed: Nov. 5, 2004

(30) Foreign Application Priority Data
Nov. 21, 2003 (JP) 2003-392183

(51) Int. Cl. H01L 21/00; H01L 31/00; H01L 21/477

(52) U.S. Cl. 257/443; 438/151; 438/795

(57) ABSTRACT

Exemplary embodiments of the invention provide, on a transparent substrate, at least a part of at least one of wiring lines, electronic elements, and pixel electrodes formed by film-forming. Before and after the film-forming, an interlayer insulating film is formed. After the film-forming or the interlayer insulation, a heat treatment is performed on the transparent substrate in a single substrate process by a heater. Thus, it is possible to manufacture an electro-optical device with good productivity and high efficiency.

### BACKGROUND OF THE INVENTION

1. Field of Invention

Exemplary embodiments of the present invention relate to a method of manufacturing an electro-optical device, such as a liquid crystal device, and an annealing device for a quartz substrate that performs a heat treatment on a transparent substrate for the electro-optical device.

2. Description of Related Art

In electro-optical devices, thin film transistors (hereinafter, referred to as ‘TFTs’), data lines, scanning lines, and pixel electrodes are deposited on a substrate. In a method of manufacturing the electro-optical device, if necessary, a heat treatment is performed on the substrate during deposition. In particular, in the case of forming a polysilicon type TFT on the substrate, the substrate must be subjected to a high temperature heat treatment during manufacturing. Accordingly, as the substrate, a quartz substrate having a high heat resistance and a strong shock resistance is used. The heat treatment on a substrate for such an electro-optical device is performed by a heater within a batch vertical furnace.

Related art document Japanese Patent No. 3075254 discloses performing a single wafer-processing type lamp annealing on a silicon substrate for forming a semiconductor device. The single substrate processing type may shorten the time required for all manufacturing processes compared with the batch process because the time required for single process in this type is much shorter than that in the batch process.

### SUMMARY OF THE INVENTION

However, when the lamp annealing is performed on the above-mentioned transparent substrate for the electro-optical device, the following problems may arise. That is, in the lamp annealing, a wafer is heated by infrared rays emitted from a lamp. However, since light easily passes through a glass substrate or a quartz substrate, it is impossible to heat the substrate with high efficiency.

On the other hand, in the above-described batch process, a relatively large-sized vertical furnace is used to treat plural substrates at one time for the efficiency of manufacture. However, since the large-sized furnace has a large thermal capacity, it takes a significant time for raising or dropping the temperature within the furnace. In addition, in order to give a sufficient heat to any substrate in the furnace, a heat treatment time margin must be left, whereby it is difficult to reduce a thermal budget.

Further, since a display of the electro-optical device is influenced, it is necessary to avoid scratching, as much as possible, the rear surface of the transparent substrate. Thus, during the heat treatment, the transparent substrate is supported by a lift pin within the furnace. As for the lift pin, three are provided on an approximately central position of the substrate in a triangular shape in plan view, and tips of them support the substrate.

However, in this case, the substrate may slip off the lift pin. In particular, when the pin is set into the furnace, the substrate is placed under an atmosphere of a high temperature, such that it may be curved and then slip down and bounce. Further, since the heat treatment on the quartz substrate is performed at about 1000° C. and the batch process requires a long treatment time, the quartz substrate may be curved due to its own weight.

Exemplary embodiments of the present invention are designed to solve the above discussed and/or other problems, and it is an object of the exemplary embodiments of the present invention to provide a method of manufacturing an electro-optical device that is capable of manufacturing the device with good productivity and high efficiency, and to provide an annealing device for a transparent substrate.

In order to solve the above discussed and/or other problems, in exemplary embodiments of the present invention, there is provided a method of manufacturing an electro-optical device including: a transparent substrate; and a plurality of pixel portions including wiring lines, electronic elements, and display electrodes that are deposited on the transparent substrate with interlayer insulating films interposed therebetween, the method including forming at least a part of at least one of the wiring lines, the electronic elements, and the display electrodes on the transparent substrate; forming the interlayer insulating films. before and after the film-forming step; and performing a heat treatment on the transparent substrate in a single substrate process using a heater after the film-forming or the interlayer-insulating.

According to the method of manufacturing the electro-optical device of exemplary embodiments of the present invention, in the film-forming, various conductive films including, for example, pixel electrodes, pixel switching TFTs, data lines, scanning lines, capacitor lines, and a light-shielding film, a semiconductor layer, an insulating film and the like, are formed and patterned on the transparent substrate. Moreover, the transparent substrate described herein indicates a substrate capable of transmitting light in its thickness direction, and includes a quartz substrate or a glass substrate. Further, in the interlayer-insulating performed before and after the film-forming, the interlayer insulating films are formed on the transparent substrate. These various films and the interlayer insulating films are alternately deposited, and the patterned components are electrically insulated from each other by the interlayer insulating films. With such a laminated structure, a plurality of the pixel portions are formed.

After the film-forming or the interlayer insulating, the heat treatment is performed on the substrate on which various conductive films are formed. However, in the heat treatment performed herein, (1) for example, a resistance heating type heater is used as a thermal source, and (2) a single substrate process is performed. This is because it is difficult to perform a lamp annealing on a transmissive, transparent substrate, but it is possible to provide a sufficient amount of heat by the heater to heat with good efficiency. Then, with the single substrate process, it is possible to obtain the following advantages.

In the single substrate process, since the furnace may be relatively small to the extent that only one substrate is entered, it takes almost no time to raise the temperature within the furnace. Further, since it is possible to replace the substrate quickly, and a change in the temperature within the furnace becomes small, it is possible to assign to the heat treatment process on the substrate, almost all of the required time. Additionally, in the single substrate process, since each substrate is heat-treated under the same conditions, the manufacturing variation between the substrates can be reduced to a great extent.

As a result, it is possible to lower the thermal budget and to shorten the treatment time per one substrate compared to that of the treatment by the batch process. Moreover, in the heat treatment according to exemplary embodiments of the present invention, one substrate may be treated at one time or a plurality of substrates may be treated simultaneously and in parallel by a plurality of equipments, each equipment treating one substrate.

Further, with a reduction in the treatment time, it is possible to prevent or reduce a curve caused in the substrate during the heat treatment. Thus, the productivity of the electro-optical device is enhanced.

Accordingly, it is possible to fully heighten the productivity of the electro-optical device, and to realize a reduction of the required time from a specification decision to a shipment, that is, a turn around time (TAT). Moreover, owing to the manufacturing with the good productivity, it is possible to obtain an advantage of a cost reduction.

According to an exemplary aspect of the method of manufacturing the electro-optical device of exemplary embodiments of the present invention, the heat treatment is performed using a plurality of supporting devices each having an inclined surface that comes into point or linear contact with the outer edge of the transparent substrate, in a state in which the outer edge of the transparent substrate is supported by the inclined surfaces.

In this exemplary aspect, in a state in which the transparent substrate is supported within the furnace by the plurality of supporting devices each having the inclined surface, for example, a columnar structure having a tip portion at which a tapered surface is provided, the heat treatment is performed. That is, the transparent substrate is mounted on the inclined surfaces of the supporting device such that its outer edge comes into point or linear contact with the inclined surfaces of the supporting device. Since the outer edge of the transparent substrate is supported, it is possible to avoid scratching its rear surface. Further, in this case, since the position of the substrate during the heat treatment is fixed with respect to a horizontal direction, it is possible to reduce or prevent the transparent substrate from horizontally slipping and falling out of the supporting device.

Accordingly, with the supporting device, it is possible to manufacture the electro-optical device with good productivity that is capable of providing a good display without scratched images.

According to another exemplary aspect of the method of manufacturing the electro-optical device of exemplary embodiments of the present invention, in the heat treatment, the transparent substrate is conveyed using a conveying device having inclined surfaces that come into point or linear contact with the outer edge of the transparent substrate, in a state in which the outer edge of the transparent substrate is supported by the inclined surfaces.

In this exemplary aspect, when the conveyance of the substrate is performed in the single substrate process, the transparent substrate is conveyed while being supported by the conveying device having the inclined surfaces, for example, an arm on which tapered surfaces are provided. That is, the transparent substrate is mounted on the inclined surfaces of the conveying device such that the outer edge of the transparent substrate comes into point or linear contact with the inclined surfaces. Since the outer edge of the transparent substrate is supported, it is possible to avoid scratching the rear surface. Further, since the conveying device maintains the substrate in a state in which it is fixed horizontally, it is possible to reduce or prevent the transparent substrate from horizontally slipping and falling out of the conveying device.

Accordingly, with the conveying device, it is possible to manufacture the electro-optical device with good productivity that is capable of providing a good display without scratched images.

In the above exemplary aspects, the heat treatment may be performed at a temperature of 300° C. or more and for five minutes or less.

In this case, each transparent substrate is heat-treated at a predetermined temperature of 300° C. or more and for five minutes or less. As described above, with the single substrate process, the treatment time of one substrate is rapidly reduced. According to the normal batch process, the treatment requires approximately tens of minutes to hours. Further, if the time required for raising the temperature within the furnace is added, the time required for one heat treatment reaches nearly ten hours. In comparison, in exemplary embodiments of the present invention, since the single substrate process is adopted and conditions for the treatment are optimized, it is possible to sufficiently perform the heat treatment, like the batch process, even if one heat treatment (that is, one substrate) is performed at a temperature of 300° C. or more and for five minutes or less.

In order to address and/or solve the above discussed and/or other problems, exemplary embodiments of the present invention provide an annealing device to perform a heat treatment on a transparent substrate in an electro-optical device. The electro-optical device includes: the transparent substrate; the transparent substrate; and a plurality of pixel portions including wiring lines, electronic elements, and display electrodes that are deposited on the transparent substrate with interlayer insulating films interposed therebetween. The annealing device includes: a chamber to house the transparent substrate therein; a heater to heat the transparent substrate within the chamber; and at least one of a supporting device to support the transparent substrate within the chamber and a conveying device to convey the transparent substrate to perform the heat treatment on the transparent substrate in a single substrate process.

In the annealing device of exemplary embodiments of the present invention, during a manufacturing process, the heat treatment is performed on the transparent substrate on which the wiring lines, the electronic elements and so on are formed with the interlayer insulating films interposed therebetween. At that time, a resistance heating type heater sufficiently heats the transparent substrate to be housed in the chamber.

Furthermore, the annealing device includes at least one of a supporting device to support the transparent substrate within the chamber and a conveying device to convey the transparent substrate to perform the single substrate process. The conveying device conveys the transparent substrate into the chamber, and the supporting device supports the conveyed substrate during the heat treatment. After the heat treatment, the conveying device takes out the transparent substrate from the chamber and conveys again.

Thus, the annealing device for the transparent substrate has the same advantages as those of the method of manufacturing the electro-optical device described above. That is, it is possible to reduce a variation in the manufacture of the transparent substrate and to fully heighten the manufacturing productivity of the electro-optical device. Further, it is possible to prevent or reduce a curve of the transparent substrate and to enhance the manufacture productivity of the electro-optical device. Moreover, the annealing device for the transparent substrate according to exemplary embodiments of the present invention may treat one substrate at one time or may treat in parallel a plurality of the substrates by a plurality of the chambers, the supporting device, and the conveying device.

Further, the supporting device may support the outer edge of the transparent substrate.

In this exemplary aspect, since the outer edge of the transparent substrate is supported, it is possible to avoid scratching the rear surface, which is a display surface and a reflective surface of the electro-optical device.

Furthermore, in this exemplary aspect, the supporting device may have an inclined surface that comes into point or linear contact with the outer edge of the transparent substrate to support the outer edge with the inclined surface.

The supporting device is, for example, a columnar structure having a tip portion on which a tapered surface is provided, and allows the inclined surface to come into contact with the outer edge of the transparent substrate, whereby the transparent substrate is supported. With the inclined surface, it is possible to reduce or prevent the substrate from slipping off the supporting device. Accordingly, it is possible for the supporting device to stably support the transparent substrate at a given position without contacting the surface of the transparent substrate. Thus, it is possible to reduce or prevent a scratch of the substrate.

Otherwise, the conveying device may support the outer edge of the transparent substrate.

In this exemplary aspect, the transparent substrate is conveyed in a state in which its outer edge is supported. Thus, it is possible to reduce or prevent the rear surface of the transparent substrate from being scratched.

Further, in this exemplary aspect, the conveying device may have inclined surfaces that come into point or linear contact with the outer edge of the transparent substrate to support the outer edge with the inclined surfaces.

The conveying device is, for example, an arm on which a tapered surface is provided, and allows the inclined surfaces to come into contact with the outer edge of the transparent substrate, whereby the transparent substrate is supported and conveyed as it is. At this time, with the inclined surface, the transparent substrate is fixed with respect to the horizontal direction. Thus, it is possible to reduce or prevent the transparent substrate from slipping off the conveying device.

By the way, in a related art arm used in a single substrate process of a device, such as a semiconductor device, a portion to support the substrate has a prism shape, and the substrate is lifted up and is conveyed by means of a rod portion that is inserted into the bottom of the substrate. That is, since no measures are provided to prevent the substrate from being horizontally slipped, it is apprehended that the substrate may be dropped due to the above phenomenon if this arm is applied to the transparent substrate. Therefore, according to this exemplary aspect, the conveying device can convey the substrate without contacting the surface of the substrate in a state in which the substrate is stably maintained. Thus, it is possible to reduce or prevent the substrate from being scratched.

Further, exemplary embodiments of the present invention provide a method of manufacturing an electro-optical device including: forming a film in regions on a substrate on which a plurality of substrates for the electro-optical device is formed; providing the substrate in a chamber of an annealing device via a supporting portion; and performing a heat treatment on the substrate in the chamber.

Furthermore, the substrate may be a quartz substrate.

Moreover, in providing the substrate, the outer edge of the substrate may be supported by an inclined surface of the supporting portion.

Further, in providing the substrate, the outer edge of the substrate may be supported by a plurality of supporting portions.

Furthermore, in performing the heat treatment, the heat treatment may be performed by a heater provided in the chamber.

These and other advantages of exemplary embodiments of the present invention will be apparent from exemplary embodiments described below.

### BRIEF DESCRIPTION OF THE DRAWINGS

FIG. 1 is a schematic plan view showing the entire structure of an electro-optical device;

FIG. 2 is a schematic cross-sectional view taken along the line H-H′ of FIG. 1;

FIG. 3 is a schematic equivalent circuit diagram of various elements, wiring lines and so on in a plurality of pixel portions formed in a matrix that constitutes an image display region of the electro-optical device;

FIG. 4 is a schematic plan view of a plurality of pixel groups adjacent to each other in a TFT array substrate, on which data lines, scanning lines, and pixel electrodes are formed, and shows only the structure regarding a lower layer part (a lower layer part up to a reference numeral 70 (a storage capacitor) in FIG. 6);

FIG. 5 is a schematic plan view of a plurality of the pixel groups adjacent to each other in the TFT array substrate, on which the data lines, the scan lines and the pixel electrodes are formed, and shows only a structure regarding an upper layer part (an upper layer part over the reference numeral 70 (the storage capacitor) in FIG. 6);

FIG. 6 is a schematic cross-sectional view taken along the line A-A′ when FIGS. 4 and 5 are overlapped to each other;

FIG. 7 is a schematic perspective view showing the schematic structure of an annealing device for a quartz substrate according to an exemplary embodiment;

FIG. 8 is a schematic plan view of FIG. 7;

FIG. 9 is a schematic cross-sectional view taken along the line C-C′ of FIG. 8;

FIG. 10 is a schematics plan view of an arm in the annealing device for the quartz substrate according to the exemplary embodiment;

FIG. 11 is a schematic cross-sectional view taken along the line D-D′ of FIG. 10;

FIG. 12 is a flowchart of a manufacturing method according to an exemplary embodiment; and

FIG. 13 shows a heat treatment temperature and the time required for each heat treatment according to examples and comparative examples.

### DETAILED DESCRIPTION OF PREFERRED EMBODIMENTS

Hereinafter, the exemplary embodiments of the present invention will be described with reference to the accompanying drawings.

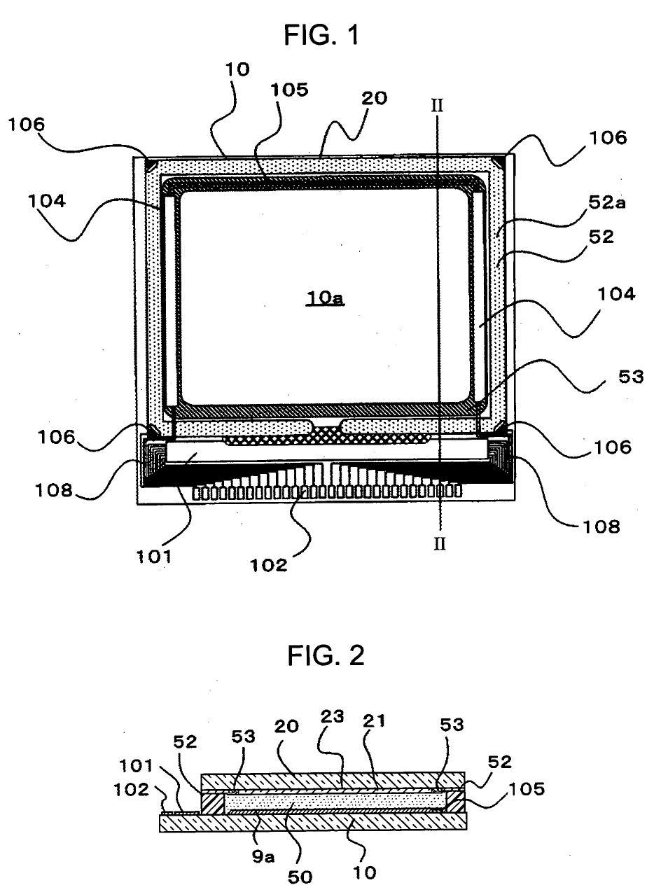

To begin with, before a method of manufacturing an electro-optical device according to exemplary embodiments of the present invention is described, the structure of an electro-optical device to be manufactured by the manufacturing method will be described with reference to FIGS. 1 to 11. Moreover, in the exemplary embodiments, a liquid crystal device is described as a specified example of the electro-optical device according to exemplary embodiments of the present invention.

<1-1: Entire Structure of Electro-Optical Device>

First of all, the entire structure of the electro-optical device according to the present exemplary embodiment will be described with reference to the FIGS. 1 and 2. FIG. 1 is a schematic plan view of the electro-optical device, seen from a counter substrate side, along with a TFT array substrate and each components formed thereon, and FIG. 2 is a schematic cross-sectional view taken along the line H-H′ of FIG. 1. Herein, as an example, an electro-optical device of a TFT active matrix driving method in which a driving circuit is embedded is described.

In FIGS. 1 and 2, the electro-optical device includes a TFT array substrate 10 and a counter substrate 20 opposite to the TFT array substrate 10. A liquid crystal layer is interpose between the TFT array substrate 10 and the counter substrate 20, and the TFT array substrate 10 and the counter substrate 20 are bonded to each other by a sealing material 52 provided in a sealing region which is at the periphery of an image display region 10a.

The sealing material 52 bonds both substrates, and is made of, for example, ultraviolet curable resin or thermosetting resin. In a manufacturing process, the sealing material 52 is coated on the TFT array substrate 10 and is then cured by ultraviolet radiation, heating and so on. Further, in the sealing material 52, a gap material composed of glass fiber or glass bead is dispersed to allow the space between the TFT array substrate 10 and the counter substrate 20 (an inter-substrate gap) to have a predetermined value.

Along the inner side of the sealing region in which the sealing material 52 is arranged, a frame light-shielding film 53 that defines a frame region of the image display region 10a is provided on the side of the counter substrate 20. However, a portion of or the entire frame light-shielding film 53 may be provided as a light-shielding film embedded in the TFT array substrate 10.

In a region outside the sealing region in which the sealing material 52 is arranged, in the periphery region, a data line driving circuit 101 and a plurality of external circuit connecting terminals 102 are provided along a side of the TFT array substrate 10. Further, scanning line driving circuits 104 are provided along two sides adjacent to the side so as to be covered with the frame light-shielding film 53. Furthermore, in order to connect between the scan line driving circuits 104 provided on both sides of the image display region 10a as described above, a plurality of wiring lines 105 are provided along a remaining side of the TFT array substrate 10 so as to be covered with the frame light-shielding film 53.

Moreover, at four corner parts of the counter substrate 20, vertical connection materials 106 that serve as vertical connection terminals between both substrates, are arranged. On the other hand, on the TFT array substrate 10, vertical connection terminals are provided at regions opposite to these corner parts. With such a structure, the electrical connection between the TFT array substrate 10 and the counter substrate 20 can be made.

In FIG. 2, on the TFT array substrate 10, pixel switching TFTs and the wiring lines, such as the scanning lines and the data lines, are formed, and then an alignment film is formed on pixel electrodes 9a. On the other hand, a light-shielding layer 23 of a lattice shape or stripe shape and a counter electrode 21 are sequentially formed on the counter substrate 20, and an alignment film is formed on the uppermost side. Further, a liquid crystal layer 50 is made of one type of nematic liquid crystal or a mixture of several types of nematic liquid crystals, and has a predetermined alignment state between a pair of the alignment films.

Moreover, on the TFT array substrate shown in FIGS. 1 and 2, in addition to the data line driving circuit 101 and the scanning line driving circuits 104, there may be formed a sampling circuit to sample an image signal on the image signal lines and to supply the sampled image signal to the data lines, a pre-charging circuit to supply pre-charging signals of a predetermined voltage level to a plurality of the data lines respectively prior to the sampled image signal, and a test circuit to test the quality or defect of the electro-optical device during manufacture or before shipping.

<1-2: Structure of Main Parts of Electro-Optical Device>

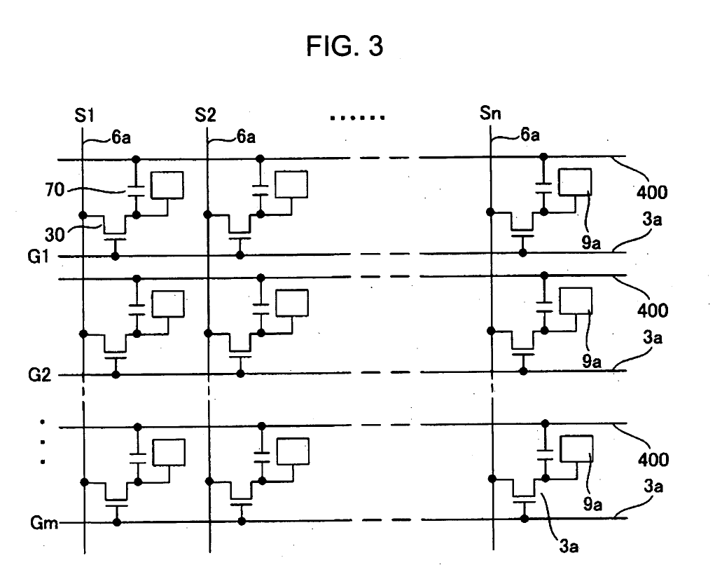

Next, the structure of the main parts of the electro-optical device according to exemplary embodiments of the present embodiment will be described with reference to FIGS. 3 to 6.

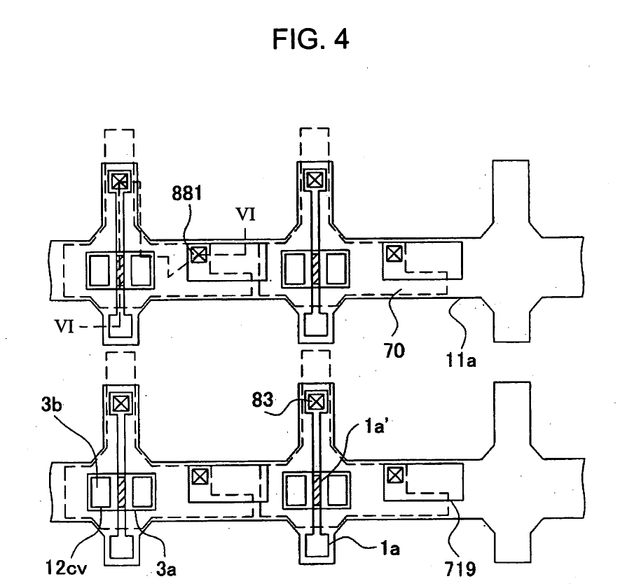

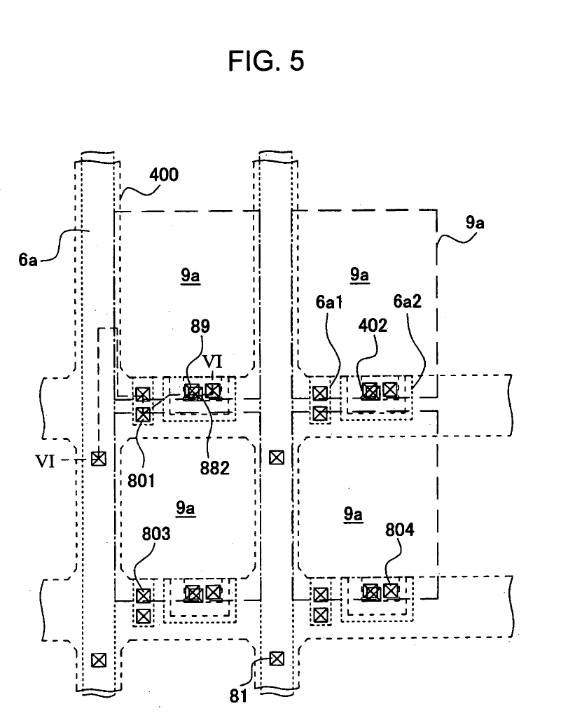

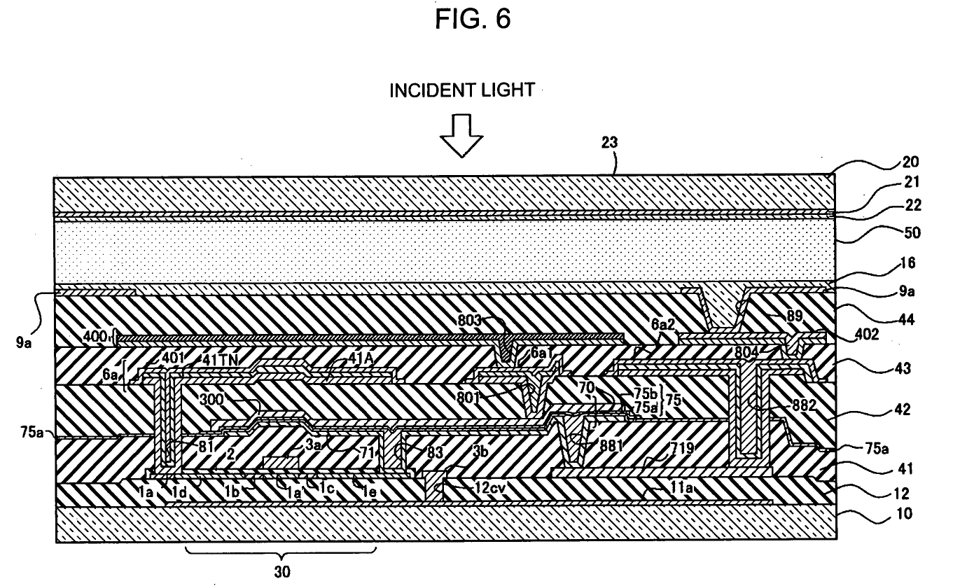

FIG. 3 shows a schematic circuit diagram of pixel portions in the electro-optical device according to the present exemplary embodiment. FIGS. 4 and 5 are schematic plan views illustrating partial configurations of the pixel portions on the TFT array substrate. FIGS. 4 and 5 respectively correspond to a lower layer portion (FIG. 4) and an upper layer portion (FIG. 5) in a laminated structure described below. FIG. 6 is a schematic cross-sectional view taken along the line A-A′ when FIGS. 4 and 5 are overlapped with each other. Moreover, in FIG. 6, the respective layers and members are shown in sizes appropriate for understanding the drawing, and a reduced scale ratio of each layer and each member may be changed appropriately.

<1-2-1: Principal Structure of Pixel Portion>

As shown in FIG. 3, in the image display region 10a, a plurality of scanning lines 11a and a plurality of data lines 6a are arranged to intersect each other, and between the lines, a pixel portion which is selected by one of the scan lines 11a and one of the data lines 6a is provided. In each pixel portion, a TFT 30, a pixel electrode 9a, and a storage capacitor 70 are provided. The TFTs 30 are provided to apply image signals S1, S2, . . . , Sn from the data lines 6a to selected pixels, respectively. The TFT 30 has a gate connected to the scanning line 11a, a source connected to the data line 6a, and a drain connected to the pixel electrode 9a. The pixel electrode 9a forms a liquid crystal capacitor along with a counter electrode 21 described below, whereby the input image signals S1, S2, . . . , Sn are applied to the pixel portions and is maintained for a constant period. An electrode of the storage capacitor 70 is connected to the drain of the TFT 30 in parallel to the pixel electrode 9a, and the other electrode thereof is connected to a capacitor line 400 of a fixed potential in order to have a constant potential.

The electro-optical device utilizes, for example, a TFT active matrix driving method in which scanning signals G1, G2, . . . , Gm are sequentially applied to the scanning lines 11a from the scanning line driving circuits 104 (see FIG. 1) respectively, and so for rows of selected pixel portions in a horizontal direction when the TFTs are turned on, image signals S1, S2, . . . , Sn are applied through the data lines 6a from the data line driving circuit 101 (see FIG. 1), respectively. Accordingly, an image signal is supplied to the pixel electrode 9a corresponding to the selected pixel. The TFT array substrate 10 is arranged opposite to the counter substrate 20 with the liquid crystal layer 50 interposed therebetween (see FIG. 2). Therefore, if an electric field is applied to the liquid crystal layer 50 in each pixel region partitioned as described above, the quantity of the transmitted light between both substrates is controlled in each pixel region, and an image is displayed according to a gray scale level. Further, at the same time, the storage capacitor reduces or prevents the image signal maintained in each pixel region from leaking.

<1-2-2: Concrete Structure of Pixel Portion>

Next, the concrete structure of the pixel portion realizing the above-mentioned operation will be described with reference to FIGS. 4 to 6.

In FIGS. 4 to 6, each circuit element in the above-described pixel portion is constructed on the TFT array substrate 10 as a patterned and laminated conductive film. The TFT array substrate 10 of the present exemplary embodiment is composed of a quartz substrate, and is arranged opposite to the counter substrate 20 formed of a glass substrate or a quartz substrate. Further, each circuit element includes, sequentially from the bottom, a first layer including the scanning lines 11a, a second layer including gate electrodes 3a, a third layer including capacitor electrodes to be at the fixed potential side of the storage capacitor 70, a fourth layer including the data lines 6a and so on, a fifth layer including the capacitor lines 400 and so on, and a sixth layer including the pixel electrodes 9a and so on. Furthermore, a base insulating layer 12 between the first and second layers, a first interlayer insulating film 41 between the second and third layers, a second interlayer insulating film 42 between the third and fourth layers, a third interlayer insulating film 43 between the fourth and fifth layers, and a fourth interlayer insulating film 44 between the fifth and sixth layers are provided respectively to reduce or prevent the above-described elements from being shorted. Moreover, among these elements, the first to third layers are shown in FIG. 4 as a lower layer portion, and the fourth to sixth layers are shown in FIG. 5 as an upper layer portion.

(Structure of First Layer—Scanning Lines and So On)

The first layer is composed of the scanning lines 11a. The scanning line 11a is patterned to have a main line portion extending along the X direction of FIG. 4 and a protruding portion extending along the Y direction of FIG. 4 in which a data line 6a or a capacitor line 400 is extended. Such a scan line 11 a is made of, for example, conductive polysilicon, but may be made of a simple metal substance containing at least one of high melting point metals, such as titanium (Ti), chromium (Cr), tungsten (W), tantalum (Ta), molybdenum (Mo), an alloy thereof, metal silicide, polysilicide, or a laminated structure of them.

(Structure of Second Layer—TFT and So On)

The second layer is composed of the TFT 30 and a relay electrode 719. The TFT 30 has an LDD (Lightly Doped Drain) structure, and includes a gate electrode 3a, a semiconductor layer 1a, and an insulating film 2 including a gate insulating film to insulate the gate electrode 3a from the semiconductor layer 1a. The gate insulating film is made of, for example, a thermally oxidized silicon oxide film, such as HTO (High Temperature Oxide). The gate electrode 3a is formed of, for example, conductive polysilicon. The semiconductor layer 1a is made of, for example, polysilicon, and is composed of a channel region 1a′, a low concentration source region 1b and a low concentration drain region 1c, and a high concentration source region 1d and a high concentration drain region 1e. Moreover, the TFT 30 preferably has an LDD structure, but may be an offset structure in which impurities are not injected into the low concentration source region 1b and the low concentration drain region 1c, or may be a self-aligned structure in which, using the gate electrode 3a as a mask, an impurity is injected at high concentration, thereby forming a high concentration source region and a high concentration drain region. Further, the relay electrode 719 is formed with the same film as that of the gate electrode 3a.

The gate electrode 3a of the TFT 30 is electrically connected to the scanning line 11a via a contact hole 12cv which is formed in the base insulating film 12. The base insulating film 12 is made of, for example, a silicon oxide film, such as HTO or an NSG (nonsilicate glass) film. By forming the base insulating film 12 on the entire surface of the TFT array substrate 10, the base insulating film 12, in addition to functioning as an interlayer insulation function between the first and second layers, functions to reduce or prevent a change of the characteristics of the TFT 30 due to a chap or a stain generated when the substrate is polished.

(Structure of Third Layer—Storage Capacitor and So On)

The third layer is composed of the storage capacitor 70. The storage capacitor 70 is configured such that a capacitor electrode 300 and a lower electrode 71 are arranged opposite to each other with a dielectric film 75 interposed therebetween. Among these elements, the capacitor electrode 300 is electrically connected to the capacitor line 400. The lower electrode 71 is electrically connected to the high concentration drain region 1e of the TFT 30 and the pixel electrode 9a.

The lower electrode 71 and the high concentration drain region 1e are connected to each other through a contact hole 83 formed in the first interlayer insulating film 41. Further, the lower electrode 71 and the pixel electrode 9a are connected to each other in a contact hole 89, and between which contact holes 881, 882, and 804, and a relay electrode 719, a second relay electrode 6a2 and a third relay electrode 402 relay each layer.

The capacitor electrode 300 is composed of a simple metal substance containing at least one of high melting point metals, such as Ti, Cr, W, Ta, and Mo, an alloy thereof, metal silicide, poly silicide, a laminated structure of them, or preferably tungsten silicide. With such a structure, the capacitor electrode has a function that shields light incident on the TFT 30. Further, for the lower electrode 71, conductive polysilicon, for example, is used.

The dielectric film 75 is made of, for example, a silicon oxide film, such as an LTO film or a HTO film that has a relatively thin film thickness of about 5 to 200 nm, or a silicon oxide film.

Further, the first interlayer insulating film 41 is made of, for example, NSG. Besides, as the first interlayer insulating film 41, silicate glass, such as PSG (phospho-silicate glass), BSG (boro-silicate glass), or BPSG (boro-phospho-silicate glass), silicon nitride, or silicon oxide may be used.

Moreover, in this case, as apparent from the schematic plan view of FIG. 4, since the storage capacitor 70 is formed not so as to reach the pixel region that nearly corresponds to a forming region of the pixel electrode 9a (to be fitted into a light-shielding region), a large aperture ratio of a pixel is maintained.

(Structure of Fourth Layer—Data Lines and So On)

The fourth layer is composed of the data line 6a. The data line 6a is formed of a three-layered film of, sequentially from the bottom, aluminum, titanium nitride, and silicon nitride. The silicon nitride layer is patterned in a somewhat large size to cover the underlying aluminum layer and titanium nitride. Further, in the fourth layer, a capacitor line relay layer 6a1 and the second relay electrode 6a2 are formed of the same film as that of the data line 6a. As shown in FIG. 5, these are divided from each other.

Among these elements, the data line 6a is electrically connected to the high concentration source region 1d of the TFT 30 via a contact hole 81 passing through the first interlayer insulating film 41 and the second interlayer insulating film 42.

Further, the capacitor line relay layer 6a1 is electrically connected to the capacitor electrode 300 via a contact hole 801 formed in the second interlayer insulating film 42, and relays between the capacitor electrode 300 and the capacitor line 400. As described above, the capacitor line relay layer 6a2 is electrically connected to the relay electrode 719 via the contact hole 882 passing through the first interlayer insulating film 41 and the second interlayer insulating film 42. Such a second interlayer insulating film 42 is made of, for example, NSG and may also be made of silicate glass, such as PSG, BSG, or BPSG, silicon nitride, or silicon oxide.

(Structure of Fifth Layer—Capacitor Line and So On)

The fifth layer is composed of the capacitor line 400 and the third relay electrode 402. The capacitor line 400 is extended up to the periphery of the image display region 10a, and is electrically connected to a constant potential source to have a fixed potential. As shown in FIG. 5, the capacitor line 400 is provided in a lattice shape extending in the X and Y directions. In a portion extending in the X direction, a notch for ensuring a forming region of the third relay electrode 402 is provided. Further, in order to cover the underlying data line 6a, the scanning line 11a, the TFT 30 and so on, the capacitor line 400 is formed to have a width larger than those of the other elements.

Such a capacitor line 400 is electrically connected to the capacitor line relay layer 6a1 via a contact hole 803 formed in the third interlayer insulating film 43.

Further, in the fifth layer, the third relay electrode 402 is formed of the same film as that of the capacitor line 400. As described above, the third relay electrode 402 relays between the second relay electrode 6a2 and the pixel electrode 9a via the contact hole 804 and the contact hole 89. Moreover, the capacitor line 400 and the third relay electrode 402 have, for example, a two-layered structure of aluminum and titanium nitride.

Below such a fifth layer, the third interlayer insulating film 43 is formed on the entire surface. The third interlayer insulating film 43 can be made of silicate glass, such as NSG, PSG, BSG, or BPSG, silicon nitride, or silicon oxide.

(Structure of Sixth Layer—Pixel Electrode and So On)

On the entire surface of the fifth layer, a fourth interlayer insulating film 44 is formed. Further, on the fourth interlayer insulating film, the pixel electrode 9a is formed as the sixth layer. In the fourth interlayer insulating film 44, the contact hole 89 is formed to electrically connect the pixel electrode 9a to the third relay electrode 402. The fourth interlayer insulating film 44 can be made of silicate glass, such as NSG, PSG, BSG, or BPSG, silicon nitride, or silicon oxide.

The pixel electrode 9a (shown in a dashed line 9a′ in FIG. 5) is arranged in each of the pixel regions divided in the horizontal and vertical directions, and the data lines 6a and the scanning lines 11 a are arranged in a lattice shape in the boundaries of the pixel regions (see FIGS. 4 and 5). Further, the pixel electrode 9a is made of, for example, a transparent conductive film, such as ITO (Indium Tin Oxide). Moreover, an alignment film 16 is formed on the pixel electrode 9a. The above is a structure of the pixel portion on the side of the TFT array substrate 10.

On the other hand, on the counter substrate 20, the counter electrode 21 is provided on the entire surface of the opposite surface. On the counter electrode 21 (in FIG. 6, the lower side of the counter electrode 21), an alignment film 22 is provided. The counter electrode 21 is made of, for example, a transparent conductive film, such as ITO, similar to the pixel electrode 9a. Moreover, between the counter substrate 20 and the counter electrode 21, a light-shielding film 23 is provided so as to cover a region facing at least the TFT 30, thereby reducing or preventing the generation of a light leak current in the TFT 30.

Between the TFT array substrate 10 and the counter substrate 20 having the above-mentioned structure, a liquid crystal layer 50 is provided. The liquid crystal layer 50 is formed by injecting liquid crystal into the space, which is formed by sealing the peripheral edges of the substrates 10 and 20 with a sealing material. In a state in which an electric field is not applied between the pixel electrode 9a and the counter electrode 21, the liquid crystal layer 50 has a predetermined alignment state by the alignment films 16 and 22 on which an alignment process, such as a rubbing process, is performed.

<2: Manufacturing Method of Electro-Optical Device>

Next, a method of manufacturing the electro-optical device according to exemplary embodiments of the present invention will be described. Further, according to exemplary embodiments of the present invention, many of the electro-optical devices can be manufactured at one time on a common quartz substrate having a relatively large size. That is, the components of the electro-optical device shown in FIG. 1 are formed in such a manner that they are arranged in a matrix shape on a quartz substrate 10M, which is a mother substrate. At that time, a heat treatment is performed on the quartz substrate 10M whenever almost all of the components are formed. Here, the heat treatment will be performed using an annealing device described below. Moreover, after manufacturing the electro-optical devices, the quartz substrate 10M is divided into a plurality of the TFT array substrate 10 by a scribing process.

<2-1: Structure of Annealing Device for Quartz Substrate>

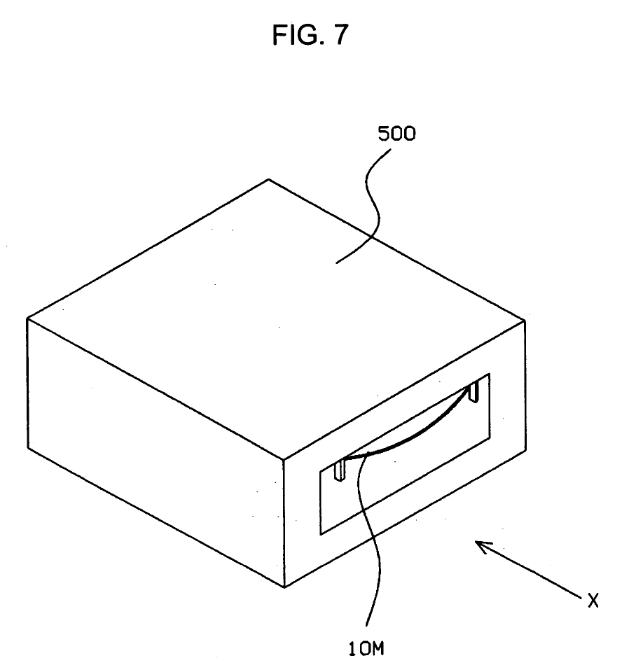

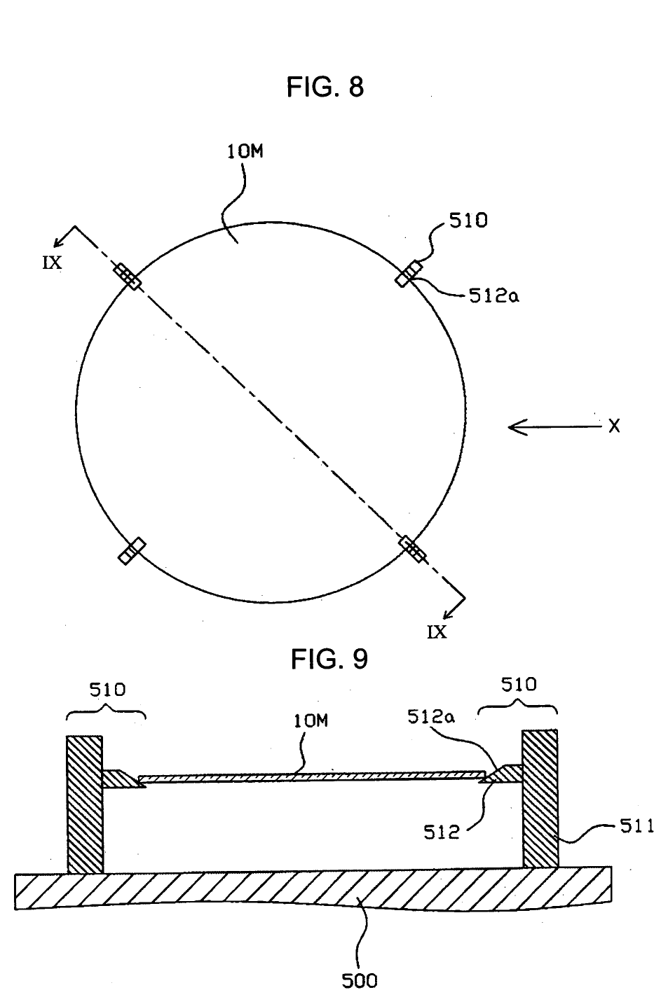

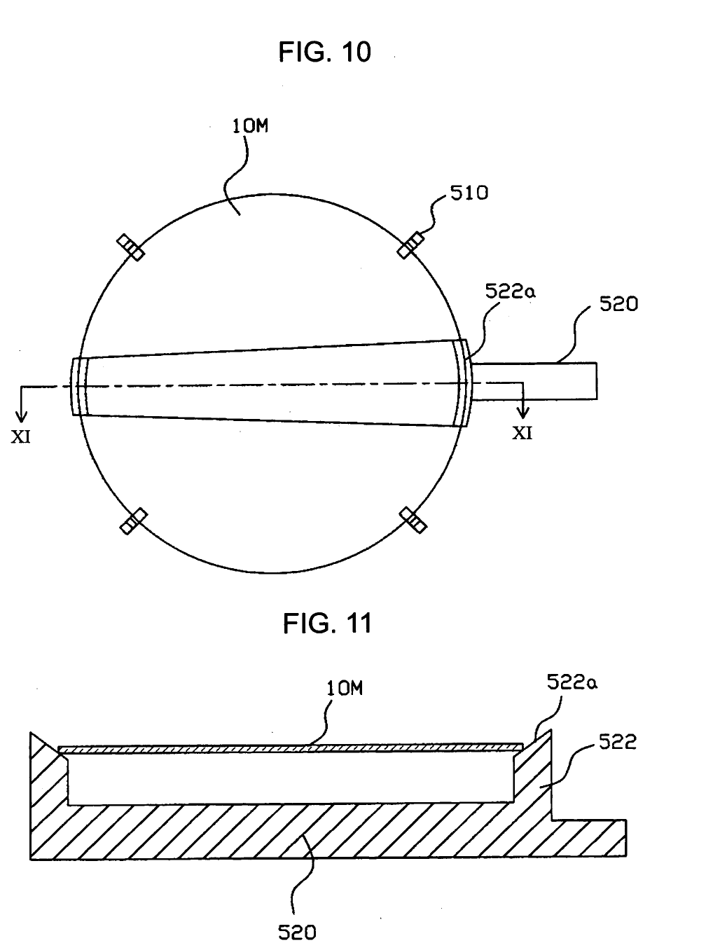

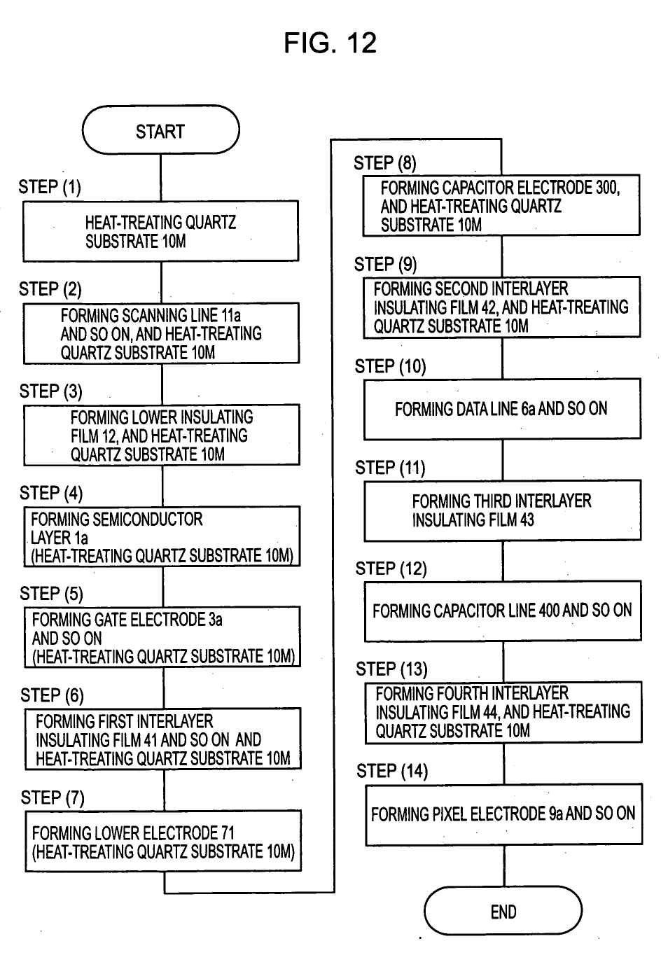

FIG. 7 is a schematic showing a chamber of an annealing device for the quartz substrate according to exemplary embodiments of the present invention. FIG. 8 is a schematic plan view showing from the upper side the main parts within the chamber shown in FIG. 7, and FIG. 9 is a schematic cross-sectional view taken along the line C-C′ of FIG. 8. Further, FIG. 10 is a schematic plan view of a lift arm of the annealing device for the quartz substrate, and FIG. 11 is a schematic cross-sectional view taken along the line D-D′ of FIG. 10.

In this device, the quartz substrate 10M is loaded in a chamber 500 in the direction of an arrow X. In a state in which the quartz substrate is housed in the chamber 500, the heat treatment is performed. This device is a single substrate processing type, and thus the chamber 500 has a size only containing exactly one quartz substrate 10M.

Further, by surrounding the periphery of the chamber 500 with hot wires, the chamber 500 is integrally formed with a heater. As described above, by using the heater as a thermal source, unlike the lamp annealing, it is possible to provide a sufficient thermal quantity to the quartz substrate 1 OM, thereby heating efficiently. Moreover, since a power source unit connected to the hot wires, a thermometer for measuring the temperature inside the chamber 500, and a temperature control unit which is connected to the thermometer and the power source unit and which is used for controlling the temperature inside the chamber 500, are the same as those in a normal annealing device, their drawings and descriptions have been omitted.

In the present exemplary embodiment, a plurality of supporting devices to support and secure the quartz substrate 10M is provided within the chamber 500. The supporting devices 510 are made of, for example, quartz, and are arranged to support the outer edge of the quartz substrate 10M, for example, in four directions as shown in FIG. 8.

Further, each of the supporting devices 510 is composed of a pillar-shaped main body portion 511 and a lift portion 512 protruding from the side surface of the main body portion 511. The lift portion 512 is, for example, in a prismatic shape, and at the tip, there is provided an inclined surface 512a in such a manner that the normal is directed to obliquely over the central side of the quartz substrate 10M. That is, the supporting device 510 is configured to support the outer edge of the quartz substrate 10M in the inclined surface 512a. The inclined surface 512a may be, for example, a flat surface or a curved surface shaped like the outer circumferential shape of the quartz substrate 10M. In the former case, the inclined surface 512a will contact the outer edge of the quartz substrate 10M at one point, or in the latter case, the inclined surface 512a will linearly contact the outer edge of the quartz substrate 10M. At this time, since the position of the quartz substrate 10M during the heat treatment is fixed with respect to the horizontal direction by the inclined surfaces 512a, it is possible to reduce or prevent the transparent substrate from horizontally slipping and falling off from the supporting device 510.

Accordingly, in the heat treatment by this device, the rear surface of the quartz substrate 10M, which is a projecting surface of the electro-optical device, can avoid being scratched.

Furthermore, in the present exemplary embodiment, a conveying device 520 is used to convey the quartz substrate 10M. As shown in FIG. 10, the conveying device 520 is inserted between the supporting device 510, and is used in loading the quartz substrate 10M on the supporting device 510 or in lifting the quartz substrate 10M and in taking it out of the chamber 500. A main body of the conveying device 520, for example, has lift portions 522 respectively at positions corresponding to both ends of the diameter of the quartz substrate 10M. Here, the lift portion 522 has a curved shape similar to the outer circumference of the quartz substrate 10M, and at the tip, an inclined surface 522a is provided. That is, the conveying device 520 is configured to support and fix the outer edge of the quartz substrate 10M on the inclined surfaces 522a.

For this reason, during the conveyance, it is possible to reduce or prevent the rear surface of the quartz substrate 10M from being scratched and to reduce or prevent the substrate from slipping and falling.

Moreover, in the present exemplary embodiment, four supporting device 510 are arranged at equal intervals along the circumference of the quartz substrate 10M of a disk shape. The number of the supporting devices 510 is limited to four, and may be two or more. Further, the interval may be irregular. However, it is preferable to provide three or more supporting devices or to arrange supporting device at equal intervals, such that when supporting the quartz substrate 10M, stability may be more enhanced.

<2-2: Manufacturing Process>

Next, a manufacturing process of the electro-optical device according to exemplary embodiments of the present invention will be described with reference to FIGS. 4 to 6 and 12. FIG. 12 is a flowchart showing the steps of forming a laminated structure on the quartz substrate 10M.

Step (1). To begin with, a quartz substrate is prepared as the quartz substrate 10M. Then, a heat treatment is performed on this substrate, in which it is pre-treated to reduce a strain to be generated in the quartz substrate 10M by a high temperature treatment which is performed later.

This heat treatment, which is a single substrate process using the above-described annealing device for the quartz substrate, is performed under an inert gas atmosphere, such as N₂ (nitrogen), and at a high temperature of about 850 to 1300° C., preferably 1000° C. At that time, the quartz substrate 10M is conveyed in a state in which the outer edge thereof is fixed and supported by the conveying device 520, and is then heat-treated in a state in which the outer edge thereof is fixed and supported by the supporting device 510, within the chamber 500, thereby reducing or preventing the rear surface from being scratched and damaged.

Further, since the chamber 500 has a relatively small size to the extent that only one substrate is entered, it does not take as much time as a large-sized chamber for the batch process even though the temperature inside the chamber 500 reaches about 1000° C. Further, since the replacement of the substrate is simple, and a change in temperature within the chamber 500 to be generated during the replacement becomes small, it is possible to assign almost all of the required time to an effective heat-treatment process. As a result, the heat-treatment time in this step can be shortened to, for example, about 300 seconds, and thus the heat-treatment is efficiently performed.

In addition, in this step, with the application of the single substrate process, the heat treatment is performed on each quartz substrate 10M under the same conditions, thereby remarkably reducing the manufacturing tolerance between the substrates. Further, if the time required for single heat treatment is shortened, a curve to be generated in the quartz substrate 10M during the process is prevented or reduced. That is, in such a high temperature heat treatment, if the treatment time is long, the quartz substrate 10M, which is made of quartz, will be curved due to its own weight. However, in this case, since the heat treatment time is extremely short, it is possible to complete the heat treatment before the quartz substrate 10M is largely deformed.

Step (2). Next, on the entire surface of the quartz substrate 10M, a metal film made of a metallic material, such as Ti, Cr, W, Ta, Mo, or Pd, or a metal alloy film, such as metal silicide, is formed with a film thickness of about 100 to 500 nm, preferably about 200 nm by a sputtering method, and is then patterned by a photolithography method and an etching method, thereby forming the gate line 11a having a predetermined pattern. Subsequently, on the patterned gate line 11a, a lower insulating film 12 made of NSG is formed, for example, by an atmospheric or low pressure CVD method.

Furthermore, on the quartz substrate 10M, a heat treatment is performed, for example, at 1000° C. and for 300 seconds. Other treatment conditions are the same as those in the heat treatment at the time of the entry of the substrate.

Step (3). Next, as the lower insulating film 12 of a lower layer, a high-temperature silicon oxide film (a HTO film) is formed on the surface of the quartz substrate 10M by a low pressure CVD method, a plasma CVD method or the like. Further, on the quartz substrate 10M, a heat treatment is performed, for example, at 950° C. and for 300 seconds. Other treatment conditions are the same as those in the heat treatment at the time of the entry of the substrate.

Step (4). Next, a polysilicon film is formed on the lower insulating film 12, and is then patterned by a photolithography method and an etching method, thereby forming a semiconductor layer 1a having a predetermined pattern. Further, on the quartz substrate 10M, a heat treatment is performed, for example, at 950° C. and for 300 seconds. Other treatment conditions are the same as those in the heat treatment at the time of the entry of the substrate. With such a heat treatment, the surface of the semiconductor layer 1a is thermally oxidized, whereby a gate insulating film 2 is formed. As a result, the thickness of the semiconductor layer 1a is in the range of 30 to 150 nm, preferably in the range of 35 to 50 nm. The thickness of the gate insulating film 2 is in the range of 20 to 150 nm, preferably in the range of 30 to 100 nm.

Step (5). Next, a polysilicon film is deposited with a thickness of about 100 to 500 nm by means of a low pressure CVD method, and phosphor is thermally diffused to make the polysilicon film conductive, whereby the gate electrode 3a is formed. At that time, on the quartz substrate 10M, a heat treatment is performed, for example, at 900° C. and for 200 seconds. Other treatment conditions are the same as those in the heat treatment at the time of the entry of the substrate.

After the heat treatment, the gate electrode 3a is patterned by a photolithography method and an etching method. Moreover, the relay electrode 719 is formed with the same film as that of the gate electrode 3a, and is simultaneously patterned by the photolithography method.

Step (6). Next, impurity ions are doped with two stages of low concentration and high concentration. Thus, in the semiconductor layer 1a, the low concentration source region 1b and the low concentration drain region 1c, and the high concentration source region 1d and the high concentration drain region 1e are formed. Subsequently, an NSG film is formed, for example, by a CVD method, whereby the first interlayer insulating film 41 is formed.

Further, the heat treatment is performed on the quartz substrate 10M at a temperature of 1000° C. and for 300 seconds. Other treatment conditions are the same as those in the heat treatment at the time of the entry of the substrate.

Step (7). Next, the contact holes 83 and 881 are formed by a dry etching method, such as a reactive ion etching method or a reactive ion beam etching method. Subsequently, a polysilicon film is deposited using a low pressure CVD method, and further phosphor is diffused to make the polysilicon film conductive, whereby the lower electrode 71 is formed.

At that time, on the quartz substrate 10M, a heat treatment is performed, for example, at 900° C. and for 200 seconds. Other treatment conditions are the same as those in the heat treatment at the time of the entry of the substrate. Moreover, the lower electrode 71 is patterned in a predetermined shape by for example, a dry etching method.

Step (8). Next, a dielectric film 75 composed of a high-temperature silicon oxide film (a HTO film) or a silicon nitride film is deposited with a relatively thin thickness of about 50 nm by a low pressure CVD method or a plasma CVD method. Then, a conductive polysilicon film is deposited by a low pressure CVD method and is then patterned in a predetermined shape using a dry etching method, whereby the capacitor electrode 300 is formed. With such a structure, the storage capacitor 70 is formed. Further, on the quartz substrate 10M, a heat treatment is performed, for example, at 900° C. and for 200 seconds. Other treatment conditions are the same as those in the heat treatment at the time of the entry of the substrate.

Step (9). Next, an NSG film is formed by, for example, an atmospheric CVD method, whereby the second interlayer insulating film 42 is formed. Further, on the quartz substrate 10M, a heat treatment is performed, for example, at 950° C. and for 300 seconds. Other treatment conditions are the same as those of the heat treatment when the entry of the substrate.

Step (10). Next, the data line 6a is formed on the second interlayer insulating film 42. To begin with, the contact holes 81, 801, and 882 are formed by performing a dry etching method, such as a reactive ion etching method or a reactive ion beam etching method on the second interlayer insulating film 42. Thereafter, on the entire surface of the second interlayer insulating film 42, a wiring material containing Al, such as Al or an Al alloy, is deposited by a sputtering method. Then, a photolithography method or an etching method is performed on the deposited film, whereby the data line 6a, the capacitor line relay electrode 6a1, and the second relay electrode 6a2 each having a predetermined pattern are formed.

Step (11). Next, on the surface of the quartz substrate 10M, the third interlayer insulating film 43 is formed. The third interlayer insulating film 43 is formed of a silicate glass film, such as PSG, BSG, or BPSG, a silicon nitride film, or a silicon oxide film by for example, an atmospheric or low pressure CVD method. That is, since the data line 6a containing Al is underlain, it is necessary to form the third interlayer insulating film 43 at a relatively low temperature of, for example, 400° C. or less.

Subsequently, the upper surface of the third interlayer insulating film 43 is planarized by a CMP process. More specifically, for example, while liquid slurry (a chemical polishing solution) containing silica particles is being poured on a polishing pad fixed onto a polishing plate, the upper surface of the third interlayer insulating film 43 is polished by rotating the surface (on the side of the interlayer insulating film 43) of the substrate with spindle so as to come into contact with the polishing pad. Further, before the data line 6a is exposed, the polishing process is stopped by time management or an appropriate stopper layer formed at a predetermined position.

Step (12). Next, on the third interlayer insulating film 43, the capacitor line 400 is formed. To begin with, on the third interlayer insulating film 43, the contact holes 803 and 804 are formed by a dry etching method. Thereafter, on the entire surface of the third interlayer insulating film 43, a lower layer film made of Al or an Al alloy, and an upper layer film made of titanium nitride are deposited by, for example, a sputtering method. Then, by performing a photolithography method or an etching method on the deposited films, the capacitor line 400 and the third relay electrode 402 each having a predetermined pattern are formed.

Step (13). Next, on the surface of the quartz substrate 10M, the fourth interlayer insulating film 44 is formed. The fourth interlayer insulating film 44 can be formed, for example, similar to the third interlayer insulating film 43. Further, on the quartz substrate 10M, a heat treatment is performed, for example, at 300° C. and for 300 seconds. Other treatment conditions are the same as those in the heat treatment at the time of the entry of the substrate. Moreover, the upper surface of the fourth interlayer insulating film 44 may be planarized by the CMP process.

Step (14). Thereafter, the contact hole 89 reaching the lower electrode 71 is formed by performing a dry etching method, such as a reactive ion etching method or a reactive ion beam etching method, on the fourth interlayer insulating film 44. Subsequently, an ITO film is deposited by a sputter method, and is then etched by a dry etching method, such as a reactive ion beam etching method, thereby forming the pixel electrode 9a. Further, a polyimide-based coating solution for an alignment film is applied on the surface of the quartz substrate 10M, and an alignment process, such as a rubbing process, is performed in a predetermined direction to have a predetermined pre-tilt angle, thereby forming the alignment film 16. In this way, on the quartz substrate 10M composed of the TFT array substrate 10, a laminated structure shown in FIGS. 4 to 6 is formed.

On the other hand, regarding the counter substrate 20, to begin with, a glass substrate is prepared as the counter substrate. Then, on the entire surface of the glass substrate, an ITO film is deposited with a thickness of about 50 to 200 nm by a sputtering method, whereby the counter electrode 21 is formed. Further, a polyimide-based coating solution for an alignment film is applied on the entire surface of the counter electrode 21, and then a rubbing process is performed in a predetermined direction to have a predetermined pre-tilt angle, thereby forming the alignment film 22.

Finally, the quartz substrate 10M on which each layer is formed as described above and the previously cut counter substrates 20 are bonded to each other by the sealing material such that the alignment films 16 and 22 face to each other. Within the space between both substrates formed as described above, liquid crystal in which various types of nematic liquid crystal, for example, are mixed is injected, thereby forming a liquid crystal layer 50 having a predetermined film thickness. Then, the quartz substrate 10M of the mother substrate is cut in accordance with the respective electro-optical device, whereby each electro-optical device shown in FIGS. 1 to 6 is manufactured.

In the present exemplary embodiment, since all of the heat treatment processes to be performed after and before the film-forming steps for each layer are performed using the annealing device for the quartz substrate, the following advantages are obtained: (1) it is possible to provide a sufficient thermal capacity to the quartz substrate 10M using a resistance heating type heater and to heat it with high efficiency; (2) by performing a single substrate process on the quartz substrate 10M, it is possible to reduce a thermal budget and to efficiently perform the heat treatment in a short time. As a result, it is possible to reduce the average treatment time per one substrate compared to a batch process and to greatly increase the manufacturing productivity of the electro-optical device.

Further, since the heat treatment is performed on the respective quartz substrates 10M under the same conditions, the manufacturing tolerance between the substrates is extremely reduced. In addition, since the heat treatment time for each substrate is reduced, a curve to be generated in the quartz substrate 10M during the treatment is prevented or reduced. Accordingly, the manufacturing productivity of the electro-optical device is enhanced. Moreover, as it is manufactured with good productivity, manufacturing costs thereof are also reduced.

Further, the heat treatment is performed using the supporting device 520 having the inclined surfaces 512a which contact the outer edge of the quartz substrate 10M in a point contact fashion, in a state in which the outer edge of the substrate is supported by the inclined surfaces 512a. Therefore, it is possible to avoid scratching the rear surface of the substrate and to reduce or prevent the substrate from slipping and falling out of the supporting device 510.

Furthermore, the conveyance of the substrate is performed using the conveying device 520 having the inclined surfaces 522a which contact the outer edge of the quartz substrate 10M in a linear contact fashion, in a state in which the outer edge of the substrate is fixed and supported. Therefore, it is possible to avoid scratching the rear surface of the substrate and to reduce or prevent the substrate from slipping and falling out of the conveying device 520.

Accordingly, it is possible to manufacture the electro-optical device with good productivity that is capable of providing a good display without scratched images.

### [EXAMPLES]

Next, an example according to exemplary embodiments of the present invention will be described.

Similar to the quartz substrate 10M in the exemplary embodiment, a laminated structure is formed on a quartz substrate. At that time, in the example, similar to the manufacturing process of the exemplary embodiment, the respective heat treatment steps (1) to (9) and (13) are performed in a single substrate process using the above-described annealing device for the quartz substrate.

Further, in a comparative example, a substrate is manufactured similar to the example, but the respective heat treatment steps (1) to (9) and (13) are performed in a batch process using a vertical diffusion furnace.

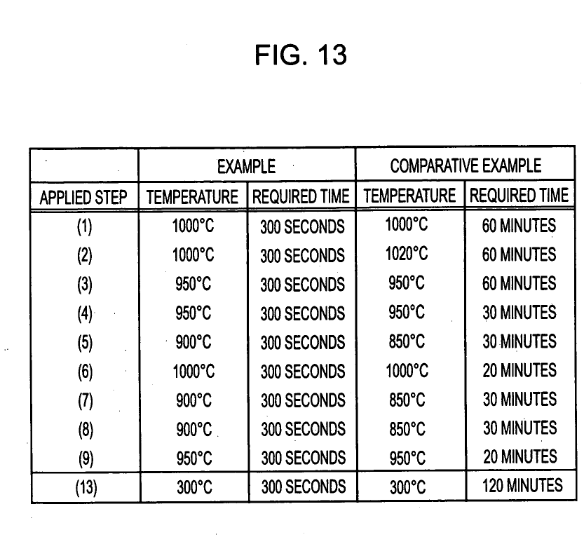

FIG. 13 shows the treatment temperature and the treatment time of the example and the comparative example in the respective heat treatment steps (1) to (9) and (13). Moreover, in the comparative example, the number of substrates to be processed by single process is set to twenty.

In the example, the treatment time of each heat treatment process is only 300 seconds in total, and it is approximately one tenth to one severalth. For this reason, in exemplary embodiments of the present invention, it is considered that a curving of the quartz substrate during the process is solved or reduced.

Comparing both of the example and the comparative example each having the same number of the substrates, it seems that, only in the effective treatment time, the heat treatment in the comparative example is quickly performed. However, in the comparative example, intervals for raising and lowering the temperature in each heat treatment of the steps (1) to (9) and (13) are needed, and then the time required for each step becomes, if short, about five hours, and if long, about nine hours. As a result, for the total time required for completing the laminated structure on the substrate, it takes about ten days in the example while it takes about fifty days in the comparative example. Therefore, according to exemplary embodiments of the present invention, it is considered that the TAT is reduced in the manufacture of the electro-optical device.

Moreover, in the exemplary embodiment and example, it is described that the quartz substrate is used as the transparent substrate for the electro-optical device. However, a glass substrate may be used. The glass substrate has a considerably low heat resistance compared with the quartz substrate and is not heat-treated at a temperature of about 400° C. or less. However, also in a heat treatment of the glass substrate, the above problems can be considered, and then with the application of exemplary embodiments of the present invention, the above effects can be obtained.

Further, in the above description, the liquid crystal device is used as a specified example of the electro-optical device according to exemplary embodiments of the present invention, but exemplary embodiments of the present invention can be applied to manufacture an electrophoresis device, such as an electronic paper, a display device (Field Emission Display and Surface-Conduction Electron-Emitter Display) using an electron emitting element, and other electro-optical devices.

Exemplary embodiments of present invention is not limited to the above-mentioned exemplary embodiment and example and can be appropriately modified within the scope of exemplary embodiments of the present invention without departing from the subject matter or concept of the exemplary embodiments of present invention read on the claims and the specification. The manufacturing method of the electro-optical device and the annealing device for the transparent substrate in accordance with such a modification also will fall into the technical scope of exemplary embodiments of the present invention.

1. A method of manufacturing an electro-optical device that includes a transparent substrate, and a plurality of pixel portions including wiring lines, electronic elements, and display electrodes that are deposited above the transparent substrate with interlayer insulating films interposed therebetween, the method comprising:
forming, above the transparent substrate, at least a part of at least one of the wiring lines, the electronic elements, and the display electrodes;
forming the interlayer insulating films before and after the film-forming; and
performing a heat treatment on the transparent substrate using a heater in a single substrate process after the film-forming or the interlayer-insulating.

2. The method of manufacturing the electro-optical device according to claim 1,
the performing the heat treatment includes using a plurality of supporting devices, each having an inclined surface that comes into one of point and linear contact with an outer edge of the transparent substrate, in a state in which the outer edge of the transparent substrate is supported by the inclined surfaces.

3. The method of manufacturing the electro-optical device according to claim 1,
the heat treatment including,
conveying the transparent substrate using a conveying device having inclined surfaces that come into one of point and linear contact with an outer edge of the transparent substrate, in a state in which the outer edge of the transparent substrate is supported by the inclined surfaces.

4. The method of manufacturing the electro-optical device according claim 1,
performing the heat treatment at a temperature of 300° C. or more and for five minutes or less.

5. An annealing device to perform a heat treatment on a transparent substrate in an electro-optical device, comprising:
the electro-optical device that includes:
the transparent substrate; and
a plurality of pixel portions including wiring lines, electronic elements, and display electrodes that are deposited above the transparent substrate with interlayer insulating films interposed therebetween,
the annealing device that includes:
a chamber to house the transparent substrate therein;
a heater to heat the transparent substrate within the chamber; and
at least one of a supporting device to support the transparent substrate within the chamber and a conveying device to convey the transparent substrate to perform the heat treatment on the transparent substrate in a single substrate process.

6. The annealing device for the transparent substrate according to claim 5,
the supporting device supporting an outer edge of the transparent substrate.

7. The annealing device for the transparent substrate according to claim 6,
the supporting device having inclined surfaces that come into one of point and linear contact with the outer edge of the transparent substrate to support the outer edge with the inclined surfaces.

8. The annealing device for the transparent substrate according to claim 5,
the conveying device supporting an outer edge of the transparent substrate.

9. The annealing device for the transparent substrate according to claim 8,
the conveying device having inclined surfaces that come into one of point and linear contact with the outer edge of the transparent surface to support the outer edge with the inclined surfaces.

10. A method of manufacturing an electro-optical device, comprising:
forming a film in regions on a substrate on which a plurality of substrates for the electro-optical device are formed;
providing the substrate in a chamber of an annealing device via a supporting portion; and
performing a heat treatment on the substrate in the chamber.

11. The method of manufacturing an electro-optical device according to claim 10,
the substrate being a quartz substrate.

12. The method of manufacturing an electro-optical device according to claim 10,
supporting, in the providing the substrate, the outer edge of the substrate by an inclined surface of the supporting portion.

13. The method of manufacturing an electro-optical device according to claim 12,
supporting, in the providing the substrate, the outer edge of the substrate by a plurality of supporting portions.

14. The method of manufacturing an electro-optical device according to claim 10,
performing the heat treatment by a heater provided in the chamber.
